(19) United States
(12) Patent Application Publication
(10) Pub. No.: US 2012/0064318 A1
(43) Pub. Date: Mar. 15, 2012

(54) TRANSPARENT BARRIER LAMINATES

(75) Inventors: Klaus Keite-Telgenbüscher, Hamburg (DE); Judith Grünauer, Hamburg (DE); Jan Ellinger, Hamburg (DE)

(73) Assignee: TESA SE, Hamburg (DE)

(21) Appl. No.: 13/264,355

(22) PCT Filed: Apr. 8, 2010
(86) PCT No.: PCT/EP2010/054628

§ 371 Date: Dec. 6, 2011

(30) Foreign Application Priority Data
Apr. 24, 2009 (DE) 102009018518.6

(51) Int. Cl. B32B 7/02; B32B 38/08

(52) U.S. Cl. 428/216; 156/182

(57) ABSTRACT

A novel, transparent, non-substrate-based permeation barrier film for encapsulating electronic, more particularly optoelectronic, assemblies consists of a first polymer layer (10), a first inorganic barrier layer (20), at least one at least partially organic compensation layer (30), at least one further inorganic barrier layer (21) and also at least one further polymer layer (11), wherein the polymer layers and the inorganic barrier layers, respectively, can be made of the same or different material, wherein the inorganic barrier layers have a thickness of between 2 and 1000 nm, and wherein the polymer layers and the at least partially organic compensation layer have a thickness of less than 5 [mu]m, preferably between 0.5 and 4 [mu]m. The film can have, on one or both sides, an auxiliary carrier attached by means of a re-releasable adhesive. It is also possible for a plurality of films to be laminated to one another by means of a further at least partially organic compensation layer.

The present invention relates to transparent permeation-barrier foils.

Transparent permeation-barrier foils of this type are used in inorganic and/or organic (opto)electronics as protection for the electronic arrangements, which are particularly susceptible to damage caused by water vapor and by oxygen.

Electronic arrangements of this type, in particular optoelectronic arrangements, are used with increasing frequency in commercial products, or are about to be introduced into the market. Arrangements of this type encompass inorganic or organic electronic structures, for example organic, organometallic, or polymeric semiconductors, or else combinations of these. These arrangements and products are of rigid or flexible design, depending on the desired use, and there is increasing demand for flexible arrangements here. Arrangements of this type are produced by way of example through printing processes, such as letterpress printing, intaglio printing, screen printing, flatbed printing, or else what is known as “non-impact printing”, for example thermal transfer printing, inkjet printing, or digital printing. However, vacuum processes are also widely used, examples being chemical gas-phase deposition (chemical vapor deposition—CVD), physical gas-phase deposition (physical vapor deposition—PVD), plasma-assisted chemical or physical gas-phase deposition (plasma-enhanced chemical or physical vapor deposition—PECVD), sputtering, (plasma) etching, or other types of vapor deposition, and the structuring here is generally produced by using masks.

Examples that may be mentioned here of electronic, in particular optoelectronic, applications that are already in commercial use or have interesting potential in the market are electrophoretic or electrochromic systems or displays, organic or polymeric light-output diodes (OLEDs or PLEDs) in indicator and display devices, or in the form of illuminants, electroluminescent lamps, light-output electrochemical cells (LLEDs), organic solar cells, preferably dye- or polymer-based solar cells, inorganic solar cells, preferably thin-layer solar cells, in particular those based on silicon, germanium, copper, indium, and selenium, organic field-effect transistors, organic switching elements, organic optical amplifiers, organic laser diodes, organic or inorganic sensors, and also organically or inorganically based RFID transponders.

A particularly important factor for achieving adequate lifetime and functioning of (opto)electronic arrangements in the field of inorganic and/or organic (opto)electronics, and very particularly in the field of organic (opto)electronics, is protection of the components present therein from permeant substances. Permeant substances can be a wide variety of low-molecular-weight organic or inorganic compounds, and particularly relevant substances are water vapor and oxygen.

A wide variety of (opto)electronic arrangements in the field of inorganic and/or organic (opto)electronics, very particularly when organic raw materials are used, are susceptible to damage caused by water vapor and also damage caused by oxygen, and the ingress of water vapor is regarded here as a major problem for many arrangements. During the lifetime of the electronic arrangement it is therefore necessary to provide protection through encapsulation of the arrangement, since otherwise performance decreases over the period of use. By way of example, the luminance of light-output arrangements, such as electroluminescent lamps (EL lamps) or organic light-output diodes (OLEDs), the contrast of electrophoretic displays (EP displays), or the efficiency of solar cells can be drastically reduced within a very short time by oxidation of the constituents.

Inorganic and/or organic (opto)electronics, in particular organic (opto)electronics, therefore has a particular requirement for flexible substrates which protect the electronic components and which represent a permeation barrier for permeant substances, such as oxygen and/or water vapor. The oxygen-transmission rate (OTR) and the water-vapor transmission rate (WVTR) are a measure of the quality of protection or of encapsulation. The respective rate here states the flow rate of oxygen and, respectively, water vapor through a film under specific conditions of temperature and relative humidity, and also partial pressure. The smaller these values, the better the suitability of the respective material for the encapsulation process. The requirements relating to the permeation barrier extend markedly beyond those in the packaging sector. WVTR<10⁻³ g/(m²d) and OTR<10⁻³/(m²d bar) are required.

A further requirement in many instances, e.g. for solar cells or outdoor displays, is that, at least on one side of the electronic cell, the material of the barrier foil has high optical transparency over a long period, including during exposure to UV and weathering.

Coextruded foils or polymeric multilayer laminates known from the packaging sector do not achieve the required values at a prescribed layer thickness. There is a restriction on layer thickness because, for example, the flexibility of the laminate decreases with increasing layer thickness and flexible laminates cannot therefore exceed a certain layer thickness. Within the prior art, there are also packaging foils combined with organic or inorganic coatings or layers. This type of coating can be applied by conventional methods, e.g. lacquering, printing, vapor deposition, sputtering, coextrusion, or lamination. Coating materials that may be mentioned here by way of non-restricting examples are metals, metal oxides, e.g. oxides or nitrides of silicon and of aluminum, and indium tin oxide (ITO), and organometallic compounds, such as those used in sol-gel coatings. EP17825269A1 and DE19623751A1 disclose an example of these types of approach to a solution.

The prior art in the field of packaging foils, in particular in respect of thin foils, has been comprehensively described in the final report of the following BMBF [German Ministry of Education and Research] project: “Verbundvorhaben: Umweltentlastung in der Produktion and Nutzung von Verpackungen aus Verbundfolien durch Halbierung des Materialeinsatzes” [Joint project: Mitigation of adverse environmental effects in the production and use of packaging made of composite foils by halving materials consumption] (1 Mar., 2003 to 31 May, 2006). Further information about the prior art is found in “Barrier Polymers” (Encyclopedia of Polymer Science and Technology, John Wiley & Sons, 3rd edition, volume 5, pages 198 to 263).

These packaging foils do not achieve the abovementioned requirements, even if, as is likewise known, they take the form of laminate of two foils with these coatings. Addition of further lamination steps is disadvantageous, given the film thickness generally used at present, which is about 12 μm in the case of polyester foil (PET), since materials consumption increases and packaging therefore becomes more expensive. Disposal costs moreover increase. Flexibility also decreases disadvantageously. The double laminates available hitherto also exhibit undesirably reduced transparency and increased light scattering (haze), attributable to bubbles embedded in the lamination adhesive.

Foils known from the packaging sector are subjected to various modifications for use in flexible (opto)electronic systems. Examples among these are covering with water-repellent layers (U.S. Pat. No. 7,306,852 B2. JP2003238911A), the use of specific lamination adhesives (WO2003040250 A1, WO2004094549A1, DE10138423 A1, WO2006/015659 A2), glassy coatings (U.S. Pat. No. 5,925,428A), the embedding of phyllosilicates or of other nanomaterials into the polymer foil, or coatings of this type (WO2007130417 A2, WO2004024989 A2), the use of polymer foils with very high glass transition temperature, heat treatment of metal-oxide-coated foils (U.S. Pat. No. 7,192,625A), and also the use of materials which ad- or absorb permeant substances (getters, scavengers) in the foil or as a coating (WO2006/036393 A2).

One technical solution hitherto has been the use of thin glass (thickness about 30-50 μm). However, the glass is very difficult to handle, and can be further processed only by specific methods, and the glass surface is very susceptible to destruction. The thin glass is therefore often laminated to a polymer foil or coated with a polymer. WO2000041978 provides a detailed explanation of the prior art. The process described there is characterized by requiring a large number of manufacturing steps for production of a glass-polymer-composite sheet. Examples of suppliers of these types of thin glass are Schott, Mainz and Corning, USA.

The requirements in respect of barrier properties are also achieved by multilayer systems of inorganic and organic layers on a carrier foil (often more than 10 layers). The inorganic layers here are generally deposited in vacuo. Examples of the prior art are described in WO 00/36665 A1, WO01/81649 A1, WO 2004/089620 A2, WO 03/094256 A2, and WO2008/057045 A1. Organic layers used often comprise acrylate-based lacquers. Currently, this technology is used commercially by Vitex Systems, San Jose, USA, and also by the Forschungsinstitut IRME [IRME Research Institute], Singapore. All of the systems mentioned require a substrate base of dimension at least 10 μm, or usually markedly more.

Hybrid materials, such as organically modified ceramics, are also used as multiple sublayers in the layer sequence, alongside inorganic and organic layers. Sol-gel technology is used here. These materials are currently being developed in collaboration between the following two institutes in Germany: the Fraunhofer-Institut für Verfahrenstechnik und Verpackung (IVV) and the Fraunhofer-Institut für Silicatforschung (ISC) (see DE19650286 and Vasko K.: Schichtsysteme für Verpackungsfolien mit hohen Barriereeigenschaften [Layer systems for packing foils with high barrier properties], dissertion at the Technical University of Munich, 2006).

Previous technical solutions for a flexible permeation barrier provide inadequate barrier effect or have a highly complex structure and often require major plant technology investment (particularly in the case of the vacuum processes). This is hindering progress toward the desired low-cost solution.

It is therefore an object of the present invention to provide a barrier foil with high transparency, low thickness, and therefore high flexibility, and also with barrier effect adequate for the encapsulation of (opto)electronic modules, in particular with respect to water vapor and oxygen, and also a process for producing same.

Said object is achieved via a transparent substrate-base-free permeation-barrier foil composed of

a first polymer layer,
a first inorganic barrier layer,
at least one at least partially organic compensation layer,
at least one further inorganic barrier layer, and also of
at least one further polymer layer,
where not only the polymer layers but also the inorganic barrier layers can respectively be composed of the same, or of different, material, and the thickness of the inorganic barrier layers is from 2 to 1000 nm, preferably from 10 to 500 nm, particularly preferably from 20 to 100 nm, and the thickness of the polymer layers and of the at least partially organic compensation layer is less than 5 μm, preferably from 0.5 to 4 μm.

This permeation-barrier foil or barrier-composite foil of the invention has the advantage that no thick, flexibility-reducing substrate is used. The thickness of these substrates in the prior art is generally at least 10 μm, and for this reason the systems produced on this type of base have very restricted possible use, if any at all, for any application that requires flexibility. Surprisingly, in contrast, we have now succeeded in depositing inorganic barrier layers without thermal or mechanical damage even onto very thin polymer layers, the overall result being production of fops of low thickness which can be made available in the form of flexible protection for electronic applications.

For the purposes of the invention, substrate-base-free means here that no substrate or carrier of thickness more than 10 μm, in particular no substrate or carrier of thickness more than 5 μm, is a permanent constituent of the foil; instead, the foil is in particular used without substrate base in the application.

Polymer layers, in particular thermoplastic polymer layers, can be oriented or stretch-oriented in order to improve their mechanical properties. In particular, they are biaxially oriented, whereupon the molecular chains of the polymer are oriented in two preferential directions by stretching. The orientation state of a polymer layer or of a foil is measured by way of the orientation birefringence (Δn) of the biaxially oriented foil or layer:

Δn=n_{MD}−n_{TD}, where n_{MD} is the optical refractive index in machine direction, i.e. longitudinally, and n_{TD} is the optical refractive index in transverse direction, i.e. transversely. If the stretching is biaxial, approximately using the same factor (degree) in the two stretching directions, which generally run perpendicularly to one another, the term used is “isotropic” or “balanced” foils, and almost identical values are measured for n_{MD} and n_{TD}. The difference Δn is then approximately zero, but n_{MD} and n_{TD} here exhibit a difference from the refractive index in the unoriented state. Anisotropic foils exhibit a particularly high level of mechanical properties in one preferential direction. Films of this type are stretched to a particularly high extent in one direction (monoaxially) and then also exhibit a markedly higher optical refractive index in this one direction when comparison is made with the other direction perpendicular thereto. The difference Δn then assumes substantial values. EP 0 193 844 gives the prior art in this connection.

In one preferred embodiment, in their two-dimensional extent, the polymer layers have orientation in at least one direction (monoaxial), and particular preference is given to orientation in two directions (biaxial). It is further preferable that these polymer layers are composed of foils, in particular of monoaxially or biaxially oriented foils. This orientation of the polymer molecules increases the mechanical stability of the polymer layer, and also the permeation barrier thereof.

Polymers that can be used are any of the transparent polymers known to the person skilled in the art and suitable for foil production, e.g. polyolefins and copolymers of these, poly(meth)acrylates, polyesters, polystyrene, polyvinyl butyral, but preference is given to use of foils with high modulus of elasticity, e.g. polyethylene terephthalate (PET), polyethylene naphthalate (PEN), polybutylene terephthalate (PST), fluoropolyester, polymethylpentene (PMP), polynorbornene, substituted polyarylates, in particular those from Ferrania, as described in Simone Angiolini, Mauro Avidano: “P-27: Polyarylate Films for Optical Applications with Improved UV-Resistance” (SID 01 DIGEST, pp. 651-653), polyimides (PI), cyclooiefin copolymers (COC), polysulfones (PSU), polyphenyl sulfone (PPSU), polyether sulfone (PESU), or polycarbonate (PC). This also applies to copolymers based on the abovementioned polymers, where “based on” means a proportion of more than 50 mol %. Particularly suitable polymers or copolymers here have a modulus of elasticity of more than 2000 MPa, preferably of more than 3000 MPa, measured at room temperature to DIN EN ISO 527 (specimen type 2, 23° C., 50% relative humidity, separation velocity 1 mm/min). High modulus of elasticity is advantageous because the polymers used in the invention are used in the form of very thin layers or, respectively, foils. High modulus of elasticity tends to prevent undesired tensile strain of the foil during the production process.

Table 1 below gives particularly suitable transparent polymers with their moduli of elasticity, and also WVTR and OTR.

TABLE 1

| | Water | Modulus of | | |
|---|---|---|---|---|
| | absorption | elasticity | WVTR | OTR |
| Type | [%] | [MPa] | [cm³/(m²d)] | [cm³/(m²d bar)] |
| PI (25 μm) | 1.8/0.8 | 2500 | 22 | 100 |
| PA6 (40 μm) | 8.0/1.5 | 1400 | 40 | 25 |
| PET (50 μm) | 0.5/0.2 | 3800 | 5 | 35 |
| PET (23 μm) | 0.5/0.2 | 3800 | 9 | 70 |
| BOPP | <0.1/<0.1 | 2200 | 0.5 | 500 |
| (40 μm) | | | | |
| COC | <0.1/<0.1 | 2400 | 0.9 | 190 |
| (100 μm) | | | | |
| PMMA | 2.1/0.6 | 1000 | 0.1 | 1100 |
| (50 μm) | | | | |
| PC (125 μm) | 0.2 | 2400 | 35 | 600 |

Very particularly suitable materials are polymers with water absorption less than 0.1% by weight, determined to DIN EN ISO 62 (method 1) at 23° C. after 24 hours, since the use of these reduces the risk of bubble formation in the composite or during the use thereof, in particular in an environment which is hot and moist.

Inorganic barrier layers having particularly good suitability are metals deposited in vacuo (e.g. by means of vaporization, CVD, PCD, PECVD), or under atmospheric pressure (e.g. by means of atmospheric plasma, reactive corona discharge, or flame pyrolysis), or in particular metal compounds, such as metal oxides, metal nitrides, or metal hydronitrides, e.g. oxides or nitrides of silicon, of boron, of aluminum, of zirconium, of hafnium, or of tellurium, and of indium-tin oxide (ITO). Materials which are likewise particularly suitable are layers of the abovementioned variants doped with further elements. A particularly suitable PVD process that may be mentioned is high-power-impulse-magnetron sputtering, which can realize particularly permeation-proof layers without subjecting the foil to any significant thermal stress.

It is preferable that the at least partially organic compensation layer is a lamination adhesive. In principle, any of the transparent solvent-containing and solvent-free lamination adhesives known to the person skilled in the art is suitable here, an example being one based on single or multicomponent polyurethanes (e.g. Liofol lamination adhesive from Henkel), on acrylates, on epoxides, on natural or synthetic rubbers, on silicates, or on silicones. Other lamination adhesives particularly suitable for the foils of the invention are those based on inorganic-organic hybrids (e.g. sol-gel technology), e.g. the lamination adhesive Inobond from Inomat, Bexbach.

Pressure-sensitive adhesive systems or hot-melt adhesive systems are also moreover particularly suitable as lamination adhesives, examples being polyolefins applied from the melt or coextruded with a polymer foil, or copolymers of these, as supplied by way of example by Clariant with trade name Licocene.

It is preferable to use systems hardened by means of actinic radiation, in particular UV radiation or electron beams, since these feature particularly low viscosities and can therefore be applied to the very thin foil without any risk of mechanical destruction. In another advantageous variant, the viscosity of the adhesive layer can also be lowered by adding solvents to reduce the viscosity of the systems, which are generally designed in the form of solvent-free adhesives.

By virtue of the low viscosities, these adhesive systems can preferably be applied by means of non-contact methods, e.g. via spraying from the aerosol phase or via curtain coating. These methods are also preferred for other adhesive systems that have sufficiently low viscosity, because they do not subject the thin polymer films to any substantial mechanical stress.

In one particularly preferred embodiment, the water-vapor transmission of the lamination adhesive is not more than 10 g/m²d and/or its oxygen transmission is not more than 100 cm³/m²d bar, since the adhesive itself then contributes to the barrier provided by the entire foil.

It is preferable that further permeation-inhibiting substances are incorporated in the form of layer or in bulk into the polymer materials or the organic material, examples being substances (getters, scavengers), such as are known to the person skilled in the art, which ab- or absorb the permeant substance, or substances which increase the permeation pathway, examples being phyllosilicates.

Foils of this type have moreover been laminated together successfully by means of a lamination adhesive without inclusion of any bubbles, and in another preferred embodiment of the invention the structure described above is therefore then subjected to at least one lamination to itself. It is possible here to retain high optical transparency (transmission>80%, particularly preferably >85%; haze<10%, particularly preferably <5%). This gives a preferred structure in the form of a specific foil laminate with particularly thin barrier foils.

The respective materials used here for the individual layers can be identical or different.

For achieving high transmission, it is advantageous if the difference between the refractive indices of the polymer, of the inorganic barrier layer, and of the at least partially organic compensation layer is not more than 0.3, in particular not more than 0.1. By way of example, this can be achieved by combining polymethyl methacrylate foil (n=1.49), SiOₓ barrier layer (n=1.5), and pressure-sensitive acrylate adhesive (n=1.48). Another example of this type of structure combines polycarbonate foil (n=1.585), AlₓO_{y} barrier layer (n=1.63), and epoxy compensation layer (n=1.6).

An advantage of multiple lamination of the same or similar structure is the simple production of very thin encapsulation foils which are highly transparent and equipped with a high barrier. This is not possible with foils of the prior art, since the multiplayer structure itself uses very thick substrate foils, and the total resultant thickness would therefore be too great to provide, for example, adequate flexibility.

The systems described above are preferably moreover equipped on part or all of at least one side with further functional layers or structuring. Examples of suitable functional layers are in particular electrically conductive layers (e.g. transparent conductive oxides, such as ITO), thermally conductive layers (e.g. layers enriched preferably with nanoscale aluminum oxide or with boron nitride), protective layers, or adhesive layers, e.g. pressure-sensitive adhesive or hot-melt adhesive. Protective layers are particularly important for transport and storage, in order to protect the foil from damage and to serve by way of example as scratch protection. A protective layer can be also be advantageous during processing of the foil, by protecting the foil by way of example from mechanical stress. Other suitable functional layers are antireflective layers or light-output layers, or light-input layers. The latter are used in particular in self-illuminating displays or solar cells, where they variably increase yield. Use of light-output layers here can increase the yield of emitted light by way of example via appropriate modification of the refractive index. The thickness of functional layers of this type is preferably less than 3 μm, in particular less than 1 μm, thus avoiding any unnecessary layer thickness increase. Structuring can preferably be brought about by embossing processes or by etching. Another advantageous embodiment combines various layers and/or structuring.

Preferred pressure-sensitive adhesives or hot-melt adhesives are those based on styrene block copolymers, on polyisobutylene, on polyisobutylene block copolymers, or on polyolefins, since these themselves provide a particularly high permeation barrier. These adhesives are described by way of example in DE 102008047964, DE 102008060113, or DE 102008062130.

These structures equipped with adhesive layers are preferably provided as adhesive tape in the form of labels, sheet materials, or rolls, and can be provided with the usual modifications known from the adhesive-tape sector, e.g. protective coverings, release liners, release layers, or protective layers.

The present invention further provides a process for producing the barrier foil of the invention, encompassing the following steps:
(a) provision of a polymer foil,
(b) coating of the polymer foil with an inorganic barrier layer to produce a composite,
(c) coating of the composite with an at least partially organic compensation layer,
(d) covering the at least partially organic compensation layer with a further composite made of polymer foil and inorganic barrier layer,
   where the polymer foil in step (a), or the composite made of polymer foil and inorganic barrier layer in step (b), is provided on a temporary carrier with an adhesive mass that can in turn be removed.

Said composite can by way of example be produced via lamination, or via other processes known to the person skilled in the art, e.g. coextrusion or coating. Polymer foil and temporary carrier here can by way of example have been bonded via any of the cohesion mechanisms known to the person skilled in the art, e.g. adhesive bonding, electrostatic interaction, or autoadhesion. In particular, this reversible cohesion can be produced via any of the materials and methods known to the person skilled in the art, in particular from the wafer-dicing or wafer-grinding sector.

One embodiment of the process therefore begins by providing a temporary carrier with a removable adhesive mass, the polymer foil being laminated onto this carrier. In a second embodiment, the temporary carrier can be applied after coating of the polymer foil with the first inorganic barrier layer has been completed. In each case, the further layers are then applied to this base. Use of the temporary carrier facilitates production of the structure, since the temporary carrier can absorb mechanical and thermal stresses that arise. Once the process has concluded, the temporary carrier can be removed. This can take place immediately after manufacture of the foil. However, it is also possible to delay removal of the foil until (immediately) prior to or after use of the foil, in such a way that the temporary carrier also serves as surface protection during storage and transport.

In another alternate embodiment, the further polymer layer, optionally with or without further inorganic barrier layer, can be equipped with a temporary carrier. Again, this temporary carrier can optionally be removed directly after the production process, or else can serve as surface protection for storage and transport.

Web tension during process steps b) to d) in roll-to-roll manufacture advantageously does not exceed the value of 25 MPa, in particular 10 MPa, thus avoiding web break-off.

The attached figures are now used for a more detailed description of the invention.

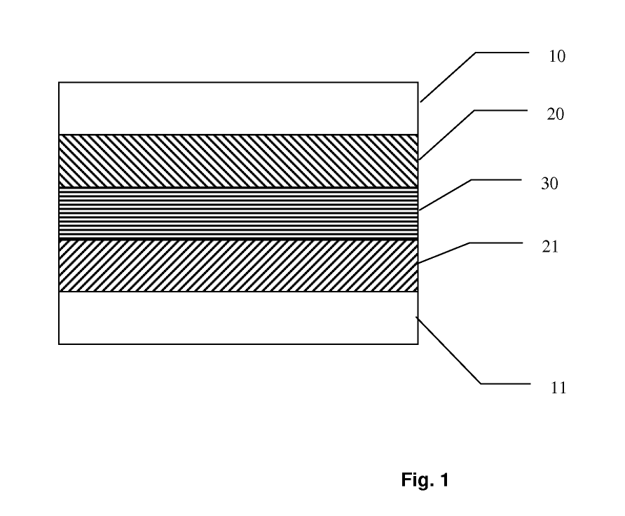

FIG. 1 is a diagram of the structure of a permeation-barrier foil of the invention.

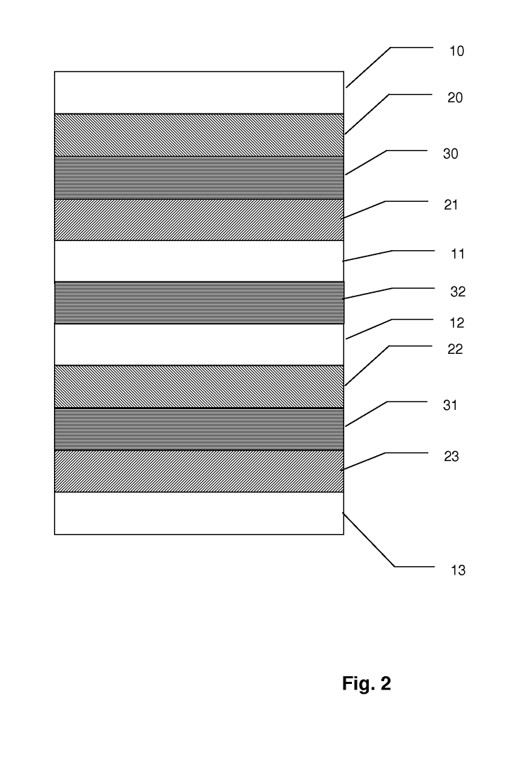

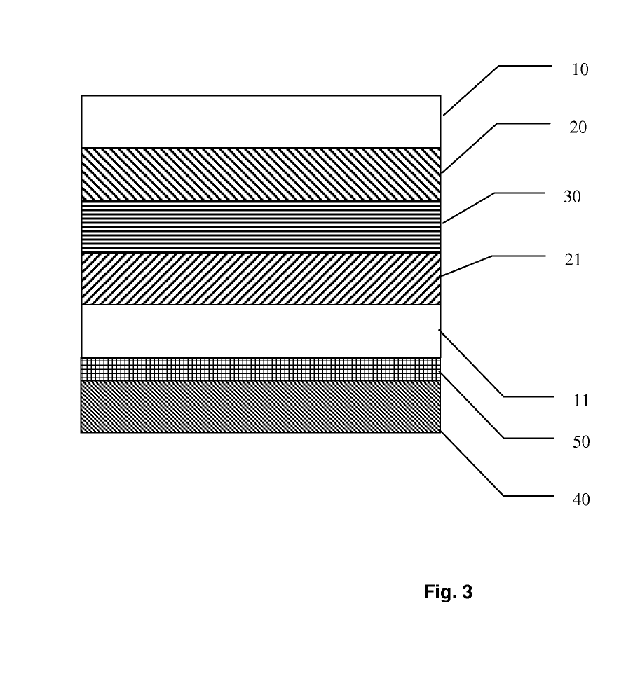

FIG. 2 is a diagram of the structure of a permeation-barrier foil composite of the invention.

FIG. 3 is a diagram of the structure of another embodiment of the permeation-barrier foil of the invention, and specifically in conjunction with a temporary carrier.

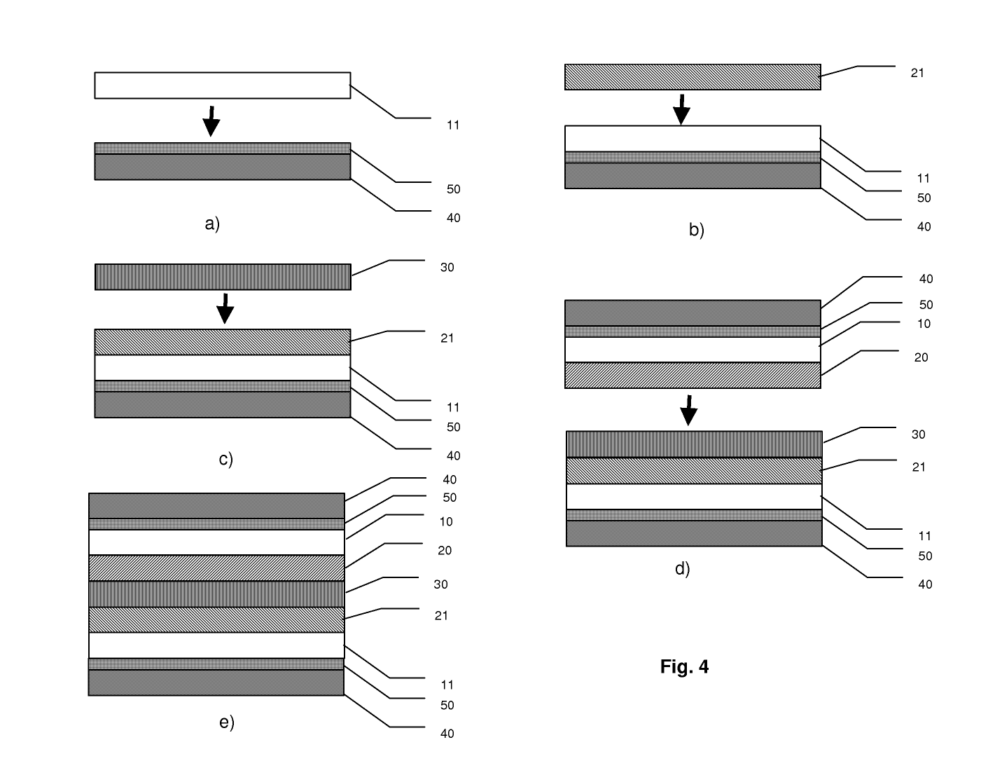

FIG. 4 is a diagram of the sequence of a first variant of the process of the invention.

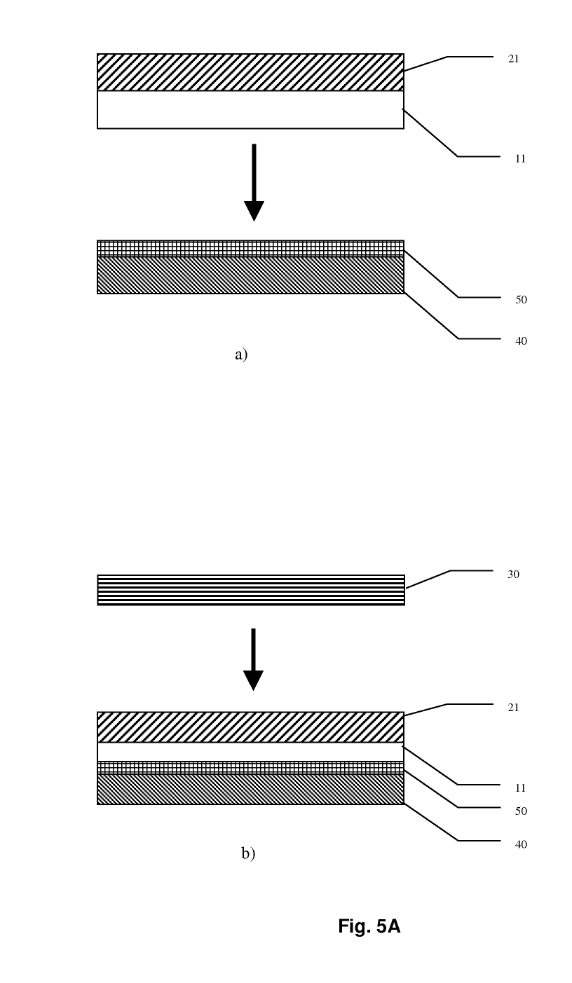

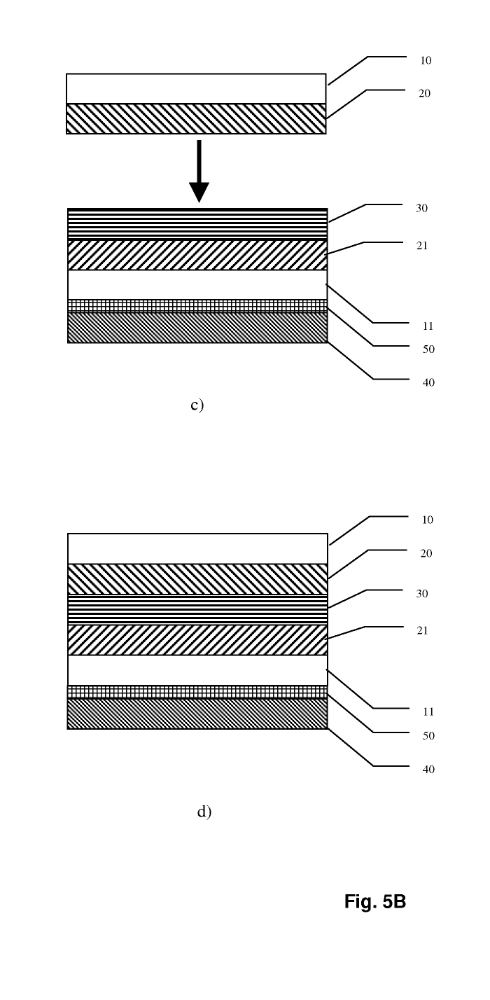

FIGS. 5A and 5B are diagrams of the sequence of a second variant of the process of the invention.

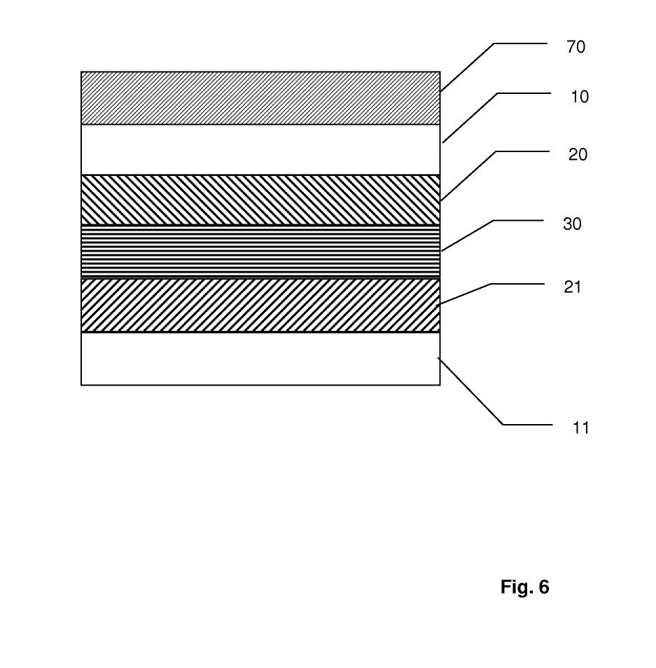

FIG. 6 is a diagram of the structure of a permeation-barrier foil of the invention with a functional layer.

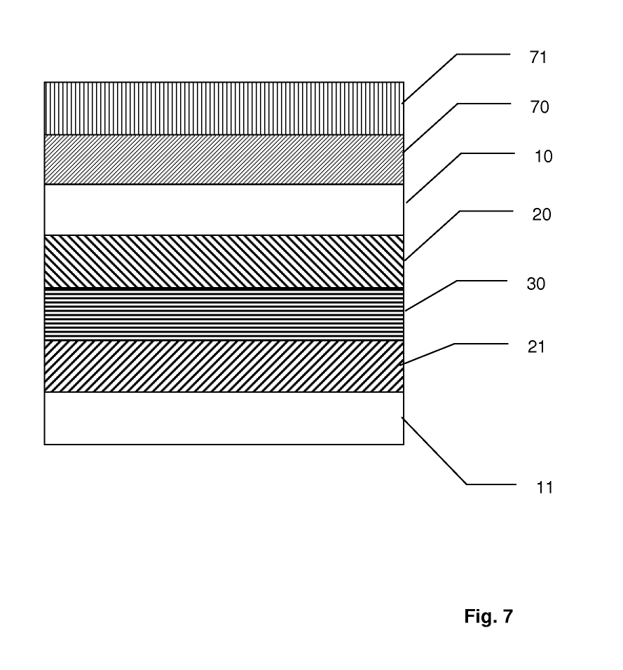

FIG. 7 is a diagram of the structure of a permeation-barrier foil of the invention with a combination of two functional layers.

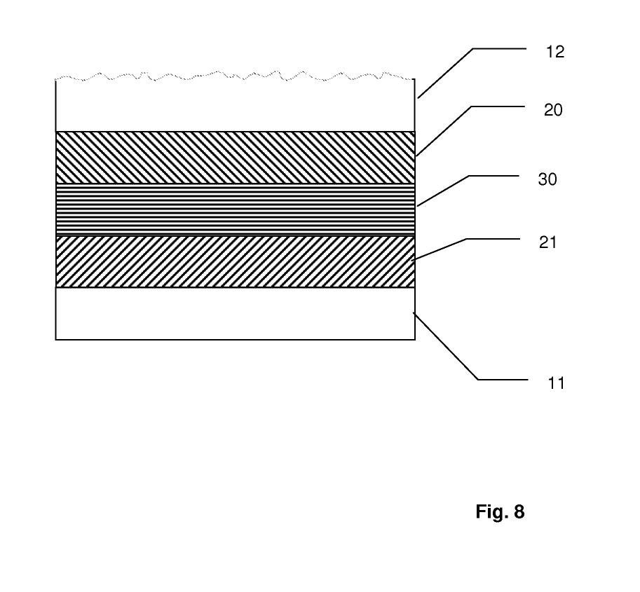

FIG. 8 is a diagram of the structure of a permeation-barrier foil of the invention with structured polymer layer.

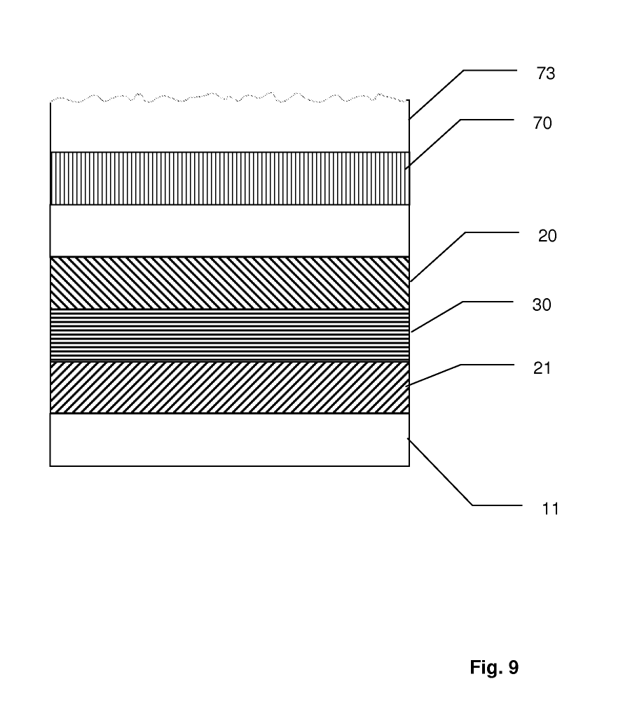

FIG. 9 is a diagram of the structure of a permeation-barrier foil of the invention with a further functional layer and a structured layer, and

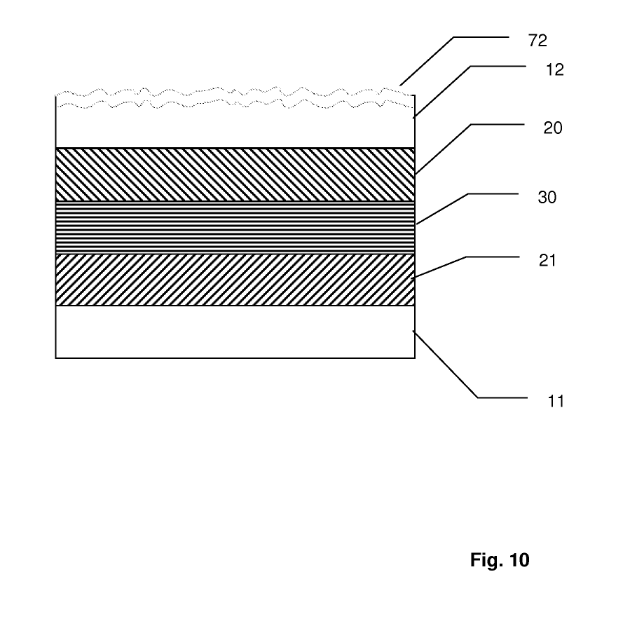

FIG. 10 is a diagram of the structure of a permeation-barrier foil of the invention with structured polymer layer combined with a very thin functional layer.

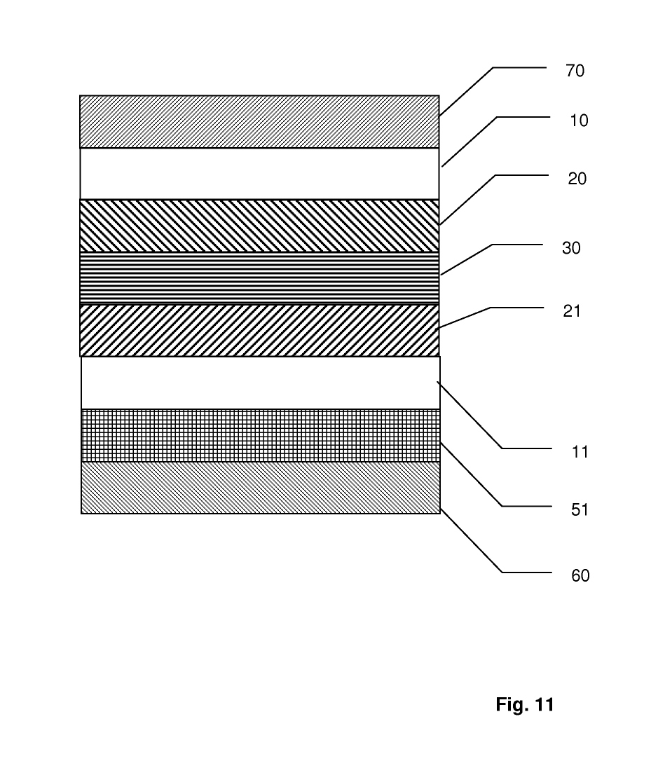

FIG. 11 is a diagram of the structure of an adhesive tape with a permeation-barrier foil of the invention, and also with a layer of pressure-sensitive adhesive mass, and with a release liner and an antireflective functional layer.

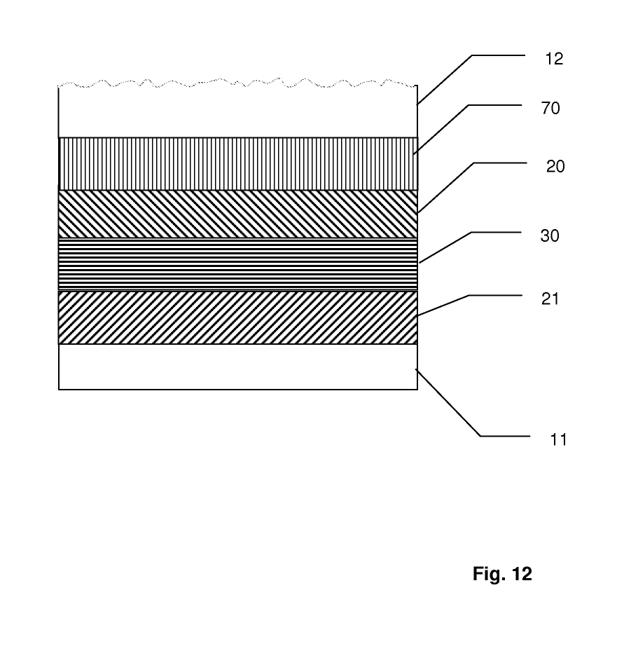

FIG. 12 is a diagram of the structure of a permeation-barrier foil of the invention with structured polymer layer combined with a functional layer.

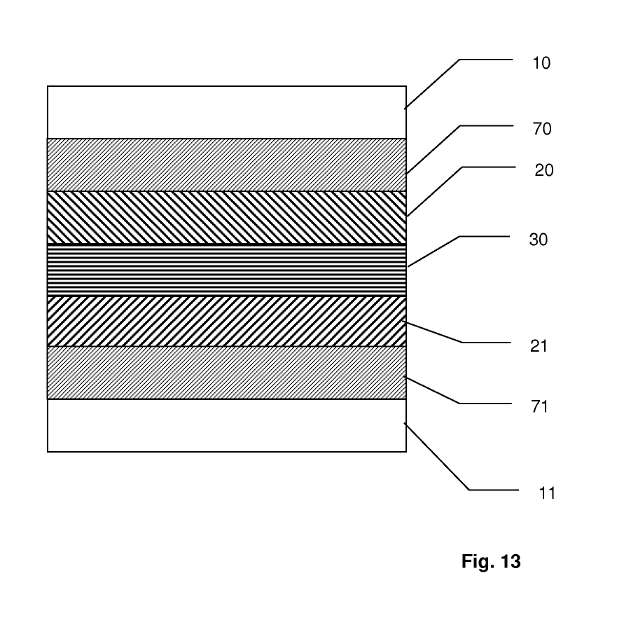

FIG. 13 is a diagram of the structure of a permeation-barrier foil of the invention with internal functional layers.

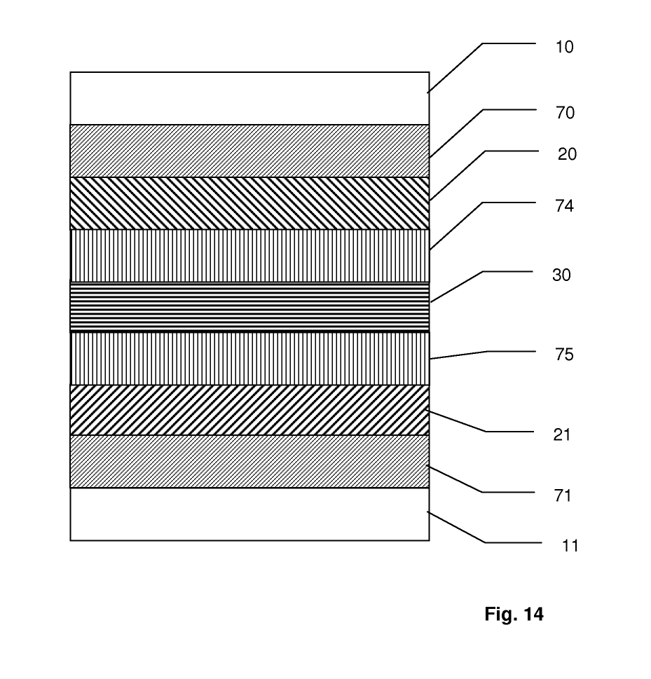

FIG. 14 is a diagram of the structure of a permeation-barrier foil of the invention with various internal functional layers.

It should be noted that expressions describing position, e.g. “on”, “over”, “top”, “thereon”, or “thereover”, and the like relating to the arrangement of the various layers in the foils or the foil composite do not necessarily indicate the absolute position, but rather indicate the position of one layer relative to another. The figures are moreover diagrams of foils. This applies in particular to the layer thicknesses shown, which are not to scale.

As shown in FIG. 1, a transparent permeation-barrier foil of the invention is composed of a first polymer layer 10, on which a first inorganic barrier layer 20 has been applied. An at least partially organic compensation layer 30 has been applied on the inorganic barrier layer to provide compensation for any holes and/or unevenness or roughness in the inorganic barrier layer. Said compensation layer is followed by a further inorganic barrier layer 21, and also by a further organic polymer layer 11. The inorganic barrier layers 20 and 21 can be composed of the same material or of different materials. Similar considerations apply to the organic polymer layers 10 and 11. If the same material is used, conduct of the process is particularly simple.

The thickness of the inorganic barrier layers is in each case from 2 to 1000 nm, preferably from 10 to 500 nm, particularly preferably from 20 to 100 nm, and the thickness of the organic polymer layers is in each case below 5 μm, preferably from 0.5 to 4 μm, particularly preferably from 1 to 2 μm. It is thus possible to provide very thin foils, i.e. foils with a thickness of only a few μm, which nevertheless form an appropriate permeation barrier to oxygen and water vapor.

In order to achieve a further improvement in barrier properties, a plurality of foils as shown in FIG. 1 can be laminated to one another. FIG. 2 shows a composite formed by laminating two foils as shown in FIG. 1 to one another. A second foil with the layer sequence first polymer layer 12—first inorganic barrier layer 22—at least partially organic compensation layer 31—second inorganic barrier layer 23—second polymer layer 13 has been laminated by means of a further at least partially organic compensation layer 32 onto a first foil with the layer sequence first polymer layer 10—first inorganic barrier layer 20—at least partially organic compensation layer 30—second inorganic barrier layer 21—second polymer layer 11. The values for WVTR and OTR in the region of 10⁻³ g/m²d or, respectively, cm³/m²d bar can easily be achieved with this type of structure, depending on the materials used, and specifically at layer thicknesses below 20 μm. A problem with foils of the prior art is that these always have a substrate base, and when a plurality of foils are laminated to one another there are therefore a plurality of these bases in the composite, and thickness values for the composite therefore rapidly become large, with resultant problems for, by way of example, flexibility.

FIG. 3 shows another embodiment. The foil shown in FIG. 3 differs from the foil shown in FIG. 1 in that the foil has been bonded to a temporary carrier 40 by means of a removable adhesive mass 50. This temporary carrier is in particular advantageous during production of the foil, since it can absorb mechanical and thermal stresses that arise. However, it also provides useful protection for the foil during storage and transport of the finished foil. FIG. 3 shows a foil which has a temporary carrier on one side. Application of the temporary carrier on both sides of the foil is equally possible.

FIG. 4 therefore shows a process for producing a foil of the invention, and specifically a foil which has a temporary carrier on both sides. Step a) shows how a polymer layer 11 is first applied to the temporary carrier 40 provided, which has a removable adhesive mass 50. In a second step, b), an inorganic barrier layer 21 is next applied. Step c) shows the application of the at least partially organic compensation layer 40. In step b), a further foil structure produced as in steps a) and b) and comprising temporary carrier 40—removable adhesive mass 50—polymer layer 10—inorganic barrier layer 20 is laminated to the foil structure obtained in step c) and specifically in such a way that the inorganic barrier layer 20 is applied to the at least partially organic compensation layer. The finished foil is then shown in e). If the inorganic barrier layers 20 and 21 and the polymer layers 10 and 11, and also temporary carrier and removable adhesive mass are all composed of the same materials, the structure of the resultant film therefore has mirror-symmetry around the at least partially organic compensation layer.

FIGS. 5A and B show an alternative process variant in which the polymer-layer side of a prefabricated composite made of polymer layer 11 and of inorganic barrier layer 21 is applied (step a)) to a temporary carrier 40 coated with a removable adhesive mass 50. In the next step b), the at least partially organic compensation layer 30 is applied to the inorganic barrier layer 21. In step c) the inorganic barrier side of a further prefabricated composite made of inorganic barrier layer 20 and polymer layer 10 is applied to said compensation layer 30, thus giving a foil with the structure of the invention comprising first polymer layer 10—first inorganic barrier layer 20—at least partially organic compensation layer 30—second inorganic barrier layer 21—second polymer layer 11, where one side of the polymer layer has been bonded by way of a removable adhesive mass 50 to a temporary carrier 40.

The permeation-barrier foil shown in FIG. 6 has a structure corresponding to that of the foil shown in FIG. 1. It also has, on one side of the first polymer layer 10, an additional functional layer 70. This can involve an electrically conductive layer, e.g. made of transparent conductive oxides, such as ITO, or can involve thermally conductive layers, e.g. layers enriched with aluminum oxide or boron nitride, or can involve adhesive layers, e.g. pressure-sensitive adhesive or hot-melt adhesive.

The barrier foil shown in FIG. 7 also comprises, in addition to the structure shown in FIG. 6, a second functional layer 71 alongside the functional layer 70. This type of foil can therefore be adapted to various requirements.

FIG. 8 shows a permeation-barrier foil of structure corresponding to that shown in FIG. 1, where the first polymer layer has been modified by structuring to give a structured polymer foil 12. The structuring permits by way of example better application of further functional layers or better anchoring of these on the layer.

The foil shown in FIG. 9 has, in addition to the barrier foil shown in FIG. 1, a further functional layer 70 on the first polymer layer 10. On the functional layer 70 there is a further polymer layer 73, which has been structured.

FIG. 10 shows a modification of the barrier foil shown in FIG. 8. The foil of FIG. 10 also has, in addition to that of FIG. 8, a very thin functional layer 72 on the structured polymer layer 12.

FIG. 11 shows an adhesive tape which encompasses a barrier foil of the invention. A barrier foil composed of a first polymer layer, of a first inorganic barrier layer 20, of an at partially organic compensation layer 30, of a further inorganic barrier layer 21, and also of a further organic polymer layer 11 has been provided with an antireflective functional layer 70 on the first polymer layer 10. The second polymer layer 11 has been bonded by way of a pressure-sensitive adhesive mass 51 to a release liner 60 as temporary carrier. Said carrier provides protection during transport and storage of the barrier foil.

FIG. 12 shows a combination of a permeation-barrier foil of the invention with structured polymer layer (12) and functional layer (70). The functional layer (70) in this foil has been arranged between first inorganic barrier layer (20) and the structured polymer layer (12).

FIG. 13 shows yet another possible arrangement. Here, the permeation-barrier foil has internal functional layers 70 and 71. These can in particular have been applied in the form of at least partially organic compensation layers on the polymeric layer, in order to provide a smooth surface for the inorganic barrier layer.

FIG. 14 shows a combination in which the permeation-barrier foil of the invention has internal functional layers 70 and 71, and also 74 and 75. Each of the functional layers 70 and 71 here has been applied as organic compensation layer on the polymeric layer, in order to provide a smooth surface for the inorganic barrier layer. The further functional layers 74 and 75 are protective layers which protect the inorganic barrier layers from damage in subsequent processes.

### INVENTIVE EXAMPLES

The following materials are used in the inventive examples below:

### Foil 1:

Kopafilm MET BOPP foil (Kopafilm, Nidda), thickness 3.5 μm

The foil was provided with an SiOₓ barrier layer of thickness about 80 nm. Coating processes of this type are carried out by, for example, the Fraunhoferinstitut für Elektronenstrahl- und Plasmatechnik (FhG-FEP) in Germany.

### Foil 2:

Hostaphan GN 4600 BOPET foil (Mitsubishi Plastics), thickness 4 μm

The foil was provided with an SiOₓ barrier layer of thickness about 80 nm. Coating processes of this type are carried out by, for example, the Fraunhoferinstitut für Elektronenstrahl- und Plasmatechnik (FhG-FEP) in Germany.

### Lamination Adhesive:

The following formulation based on UV-crosslinking resins was used as lamination adhesive:

| Trade name | Substance name | Supplier | [%] |
|---|---|---|---|
| Genomer | Urethane acrylate/urethane monomer | Rahn | 40 |
| 4269/M22 | | | |
| IBOA | Isobornyl acrylate | Cytec | 38 |
| Genomer 1122 | Urethane monomer | Cytec | 15 |
| Irgacure 500 | Photoinitiator | Ciba | 4 |
| Ebecryl 7100 | N Synergist | Cytec | 3 |
| | | Total: | 100 |

The viscosity of the lamination adhesive was 200 mPas (measured in a rotary viscometer to DIN 53019 at 23° C.).

The coating of lamination adhesive was achieved by using a halftone roller application unit with a counterrotating (80%) 140 l/cm hexagonal halftone roil, and the foil here was in slip contact with the halftone roll, i.e. not pressed into contact by any backing roll, the aim being to minimize the forces acting on the foil. Web tension was about 20 MPa.

The mass application rate was 2.5 g/m² at a web velocity of 8 m/min.

A backing roll of hardness 50 Shore is used to laminate the other foil onto the lamination adhesive before the latter had hardened.

### Inventive Example 1

Foil 1 was coated with the lamination adhesive and this composite was in turn covered with further foil 1. Hardening was achieved by using a dose of 40 mJ/cm² from a UV system from IST equipped with medium-pressure mercury sources.

### Inventive Example 2

Foil 1 was coated with the lamination adhesive and this composite was in turn covered with further foil 1. Hardening was achieved by using a dose of 80 mJ/cm² from a UV system from IST equipped with medium-pressure mercury sources.

### Inventive Example 3

The side not provided with the barrier layer in foil 2 was laminated to tesa 50550 reversible adhesive tape. The composite was coated with the lamination adhesive and covered with foil 2.

### Inventive Example 4

The foil structure from inventive example 2 was coated with the lamination adhesive and in turn covered with the foil structure from inventive example 2. Hardening was achieved by using a dose of 80 mJ/cm² from a UV system from IST equipped with medium-pressure mercury sources.

### Inventive Example 5

The foil structure from inventive example 4 was coated with the lamination adhesive and in turn covered with the foil structure from inventive example 4. Hardening was achieved by using a dose of 80 mJ/cm² from a UV system from IST equipped with medium-pressure mercury sources.

### Comparative Example 1

A quadruple laminate of a 12μ PET foil with SiOₓ coating from Alcan packaging was tested (Alcan UHBF).

Transmittance and haze to ASTM D1003-00 were determined on the resultant specimens. WVTR and OTR were measured at 38° C. and 90% relative humidity to STM F-1249 and, respectively, 23° C. and 50% relative humidity to DIN 53380, part 3. Table 2 below collates the results.

### Barrier Foil Properties.

TABLE 2

| | Thickness | Transmittance | Haze | WVTR | OTR [cm³/ |
|---|---|---|---|---|---|
| Example | [μm] | [%] | [%] | [g/m² d] | m²d bar] |
| Foil 1 | 3.5 | 91 | 2.1 | 0.04 | 0.06 |
| Foil 2 | 4 | 90 | 2.3 | 0.06 | 0.02 |
| Inventive | 9 | 89 | 4.1 | 0.015 | 0.025 |
| example 1 | | | | | |
| Inventive | 11 | 88 | 4.0 | 0.02 | 0.01 |
| example 2 | | | | | |
| Inventive | 76 | — | — | — | — |
| example 3 | | | | | |
| Inventive | 20 | 86 | 5.9 | 0.009 | 0.006 |
| example 4 | | | | | |
| Inventive | 41 | 85 | 8.9 | 0.005 | 0.004 |
| example 5 | | | | | |
| Comparative | 50 | 88.23 | 5.8 | 0.08 | 0.028 |
| example 1 | | | | | |

The examples show that the foil structure of the invention achieves very good barrier values at comparatively low foil thickness. WVTR and OTR are in the region of 10⁻² g/m²d and, respectively, cm²/cm²d bar (cf. inventive examples 1 and 2) even for foils of simple structure (layer thickness around 10 μm), and the values for a composite with doubled or quadrupled structure (cf. inventive examples 4 and 5) are in the region of 10⁻³ g/m²d and, respectively, cm³/m²d bar.

1. A transparent substrate-base-free permeation-barrier foil comprising a first polymer layer (10), a first inorganic barrier layer (20), at least one at least partially organic compensation layer (30), at least one further inorganic barrier layer (21), and also of at least one further polymer layer (11), wherein the polymer layers the inorganic barrier layers comprise the same or different material, and the thickness of the inorganic barrier layers is from 2 to 1000 nm, and in that the thickness of the polymer layers and of the at least partially organic compensation layer is less than 5 μm, preferably from 0.5 to 4 μm.

2. The permeation-barrier foil of claim 1, wherein the polymer layers have orientation in at least one direction.

3. The permeation-barrier foil of claim 1 wherein the polymer layers are comprised of monoaxially or biaxially oriented foils.

4. The permeation-barrier foil of claim 3, wherein the polymer is selected from the group consisting of polyethylene terephthalate, polyethylene naphthalate, polybutylene terephthalate, fluoro-polyester, polymethylpentene, polynorbornene, substituted polyarylates, polyimide, cycloolefin copolymers, polysulfone, polyphenyl sulfone, polyether sulfone and polycarbonates and copolymers based on polymers from this group.

5. The permeation-barrier foil of claim 1 wherein the modulus of elasticity of the polymer is more than 2000 MPa.

6. The permeation-barrier foil of claim 1 wherein the water content of the polymer is less than 1% by weight.

7. The permeation-barrier foil as of claim 1 wherein the inorganic barrier layer is comprised of metal or metal compounds deposited in vacuo or under atmospheric pressure.

8. The permeation-barrier foil of claim 7, wherein the inorganic barrier layer is comprised of a compound selected from the group consisting of oxides, nitrides, OF hydronitrides of silicon, hydronitrides of boron, hydronitrides of aluminum, hydronitrides of zirconium, hydronitrides of hafnium, of tellurium, indium-tin oxide, and one of the abovementioned compounds doped with further elements.

9. The permeation-barrier foil of claim 1 wherein the at least partially organic compensation layer is an adhesive layer of which the water-vapor transmission is not more then 10 g/m2d and the oxygen transmission is not more than 100 ce/m2d bar.

10. A permeation-barrier foil composite comprising at least two permeation-barrier foils of claim 1 wherein the foils are laminated to one another via at least one further at least partially organic compensation layer, where the permeation-barrier foils can be identical or different in respect of their materials and their structure.

11. The permeation-barrier foil of claim 1 wherein the foil is coated with a removable adhesive mass (50).

12. The permeation-barrier foil of claim 1 wherein all or part of at least one side of the foil has at least one further functional layer, and/or a structuring, where the functional layer has been selected from the group consisting of thermally or electrically conductive layers, protective layers, adhesive layers, antireflective layers, and/or light-output or light-input layers, and combinations of these layers thereof.

13. The permeation-barrier foil of claim 12, wherein the adhesive of the adhesive layer is a pressure-sensitive adhesive or a hot-melt adhesive based on styrene block copolymers, on polyisobutylene, on polyisobutylene block copolymers, or on polyolefins.

14. The permeation-barrier foil as claimed in claim 1 wherein the difference between the refractive indices of polymer layer, inorganic barrier layer, and at least partially organic compensation layer is not more than 0.3.

15. The permeation-barrier foil of claim 1 wherein the thickness of the permeation-barrier foil is less than <10 μm, its water-vapor transmission is <10⁻² gm²d, and its oxygen transmission is <10⁻² cm³/m²d bar.

16. The permeation-barrier foil composite of claim 10 wherein the thickness of the permeation-barrier foil is less than <20 μm, its water-vapor transmission is <10⁻³ gm²d, and its oxygen transmission is <10⁻³ cm³/m²d bar.

17. A process for producing a permeation-barrier foil of claim 1 comprising the following steps:
(a) providing a polymer foil (10),
(b) coating of the polymer foil with an inorganic barrier layer (20) to produce a composite,
(c) coating of the composite with an at least partially organic compensation layer (30),
(d) covering the at least partially organic compensation layer with a further composite made of polymer foil (11) and inorganic barrier layer (21), wherein the polymer foil (10) in step (a), or the composite made of polymer foil (10) and inorganic barrier layer (20) in step (b), is provided on a temporary carrier (40) with an adhesive mass that can in turn be removed.

18. (canceled)
